(19) United States
(12) Patent Application Publication
(10) Pub. No.: US 2025/0268060 A1
(43) Pub. Date: Aug. 21, 2025

(54) Display Device

(71) Applicant: LG Display Co., Ltd., Seoul (KR)

(72) Inventors: Juhwan Han, Seoul (KR); JoonWon Park, Seoul (KR)

(21) Appl. No.: 18/999,799

(22) Filed: Dec. 23, 2024

(30) Foreign Application Priority Data
Feb. 19, 2024 (KR) 10-2024-0023580

(51) Int. Cl. H10K 59/65; H10K 59/40; H10K 59/80

(52) U.S. Cl. CPC H10K 59/65; H10K 59/40; H10K 59/873

(57) ABSTRACT

Provided is a display device. The display device comprises a substrate comprising an optical area comprising a through hole, a first display area surrounding the optical area, and a second display area surrounding the first display area, a plurality of light emitting elements disposed on the substrate, and a plurality of patterns disposed on the plurality of light emitting elements in the first display area, in such a way that the plurality of patterns respectively corresponds to each of the plurality of light emitting elements.

### CROSS-REFERENCE TO RELATED APPLICATION

This application claims the priority of Republic of Korea Patent Application No. 10-2024-0023580 filed on Feb. 19, 2024, which is hereby incorporated by reference in its entirety.

### BACKGROUND

### Field

The present disclosure relates to a display device, and particularly, a display device that can minimize or at least reduce deterioration in luminance, caused around a hole.

### Description of the Related Art

Display devices may be used for various types of devices such as a TV, a monitor, a tablet computer, a navigator, a gaming device, a mobile phone and the like. They may include a variety of display devices such as a liquid crystal display (LCD) device, an organic light emitting display (OLED) device and the like.

Currently, a camera, a speaker, a sensor and the like may be added to a display device. In particular, a display device has a hole-in-display structure in which a hole is formed in the device so that a sensor such as a camera is disposed in the display device.

### SUMMARY

The objective of the present disclosure is to provide a display device that may minimize deterioration in luminance, caused around a through hole.

Another objective of the present disclosure is to provide a display device where a step between an uppermost layer among elements disposed in an optical area comprising a through hole and an uppermost layer among elements disposed in a display area is reduced.

Objects of the present disclosure are not limited to the above-mentioned objects, and other objects, which are not mentioned above, can be clearly understood by those skilled in the art from the following descriptions.

According to an embodiment of the present disclosure, there is provided a display device. The display device comprises a substrate comprising an optical area comprising a through hole, a first display area and a second display area, the first display area located between the optical area and the second display area, a plurality of light emitting elements disposed on the substrate, and a plurality of patterns disposed on the plurality of light emitting elements in the first display area, in such a way that the plurality of patterns respectively corresponds to each of the plurality of light emitting elements. Accordingly, deterioration in luminance, caused in the first display area adjacent to the through hole, may be minimized or reduced.

According to another aspect of the present disclosure, a display device may comprise a substrate comprising an optical area comprising a through hole, a first display area and a second display area, the first display area located between the optical area and the second display area; a plurality of light emitting elements disposed in the first display area and the second display area on the substrate; and a plurality of patterns disposed on an inclination surface in the first display area.

Other detailed matters of the exemplary embodiments are included in the detailed description and the drawings.

According to the present disclosure, the plurality of patterns is disposed on an inclined encapsulation part, in an area adjacent to the through hole, out of the display areas, to make an inclination caused by the step gentle.

According to the present disclosure, the plurality of patterns is disposed to respectively correspond to each of the plurality of light emitting elements, in a display area adjacent to the through hole, to minimize deterioration in luminance, caused in the display area adjacent to the through hole.

The effects according to the present disclosure are not limited to the contents exemplified above, and more various effects are included in the present specification.

### BRIEF DESCRIPTION OF THE DRAWINGS

The above and other embodiments, features and other advantages of the present disclosure will be more clearly understood from the following detailed description taken in conjunction with the accompanying drawings, in which:

FIG. 1 is a block diagram of a display device according to one embodiment;

FIG. 2 is a plan view of area A of FIG. 1 according to one embodiment;

FIG. 3 is a plan view of area B of FIG. 2 according to one embodiment;

FIG. 4 is a cross-sectional view along IV-IV′ of FIG. 2 according to one embodiment; and

FIG. 5 is a cross-sectional view along IV-IV′ of FIG. 2 in another embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

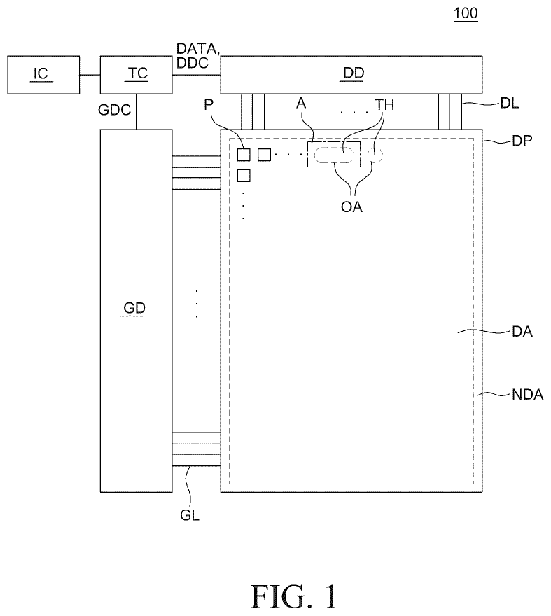

FIG. 1 is a block diagram of a display device according to one embodiment.

Referring to FIG. 1, a display device 100 of one embodiment may comprise an image processor integrated circuit (IC), a timing controller TC, a data driver DD, a gate driver GD and a display panel DP.

The image processor IC may output a data signal DATA, a data enable signal and the like provided from the outside. The image processor IC may output one or more of a perpendicular synchronization signal, a horizontal synchronization signal and a clock signal in addition to a data enable signal.

The timing controller TC may be provided with a data signal DATA together with a data enable signal or a driving signal comprising a perpendicular synchronization signal, a horizontal synchronization signal and a clock signal and the like from the image processor IC. The timing controller TC may output a gate timing control signal GDC for controlling an operation timing of the gate driver GD, and a data timing control signal DDC for controlling an operation timing of the data driver DD, based on a driving signal.

Additionally, the data driver DD may sample and latch a data signal DATA provided from the timing controller TC in response to a data timing control signal DDC provided from the timing controller TC, and convert the same to a gamma reference voltage and output the gamma reference voltage. The data driver DD may output a data signal DAA through data lines DL.

Further, the gate driver GD may output a gate signal in response to a gate timing control signal GDC provided from the timing controller TC while shifting the level of a gate voltage. The gate driver GDD may output a gate signal through gate lines GL.

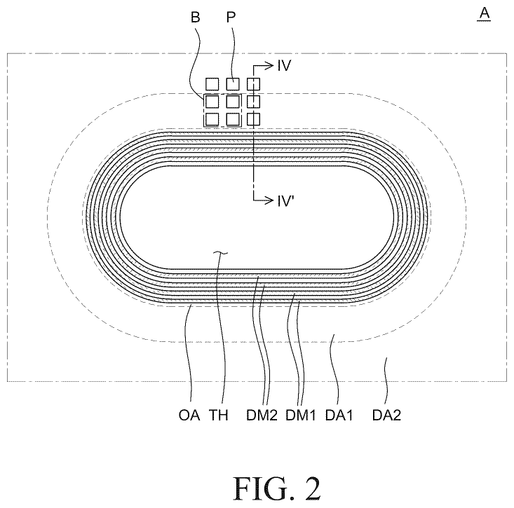

The display panel DP may display an image while a pixel P emits light, in response to a data signal DATA and a gate signal provided from the data driver DD and the gate driver GD. A detailed structure of the pixel P is described specifically with reference to FIG. 2.

The display panel DP may comprise a display area DA, an optical area OA that is disposed in the display area DA and comprises a through hole TH, and a non-display area NDA that is adjacent to (for example, surrounds) the display area DA.

The display area DA is an area of the display panel DP, where an image is displayed.

In the display area DA, a plurality of pixels P and a circuit for driving the plurality of pixels P may be disposed. The plurality of pixels P are a minimum unit constituting the display area DA, and a light emitting element 140 may be disposed in each of the plurality of pixels P. For example, an organic light emitting element comprising an anode, a light emitting layer and a cathode may be disposed in each of the plurality of pixels P, but not limited thereto.

Additionally, a driving element, lines and the like may be included in the circuit for driving the plurality of pixels P. For example, the circuit may be comprised of a thin film transistor, a storage capacitor, a gate line, a data line and the like, but not limited thereto.

The optical area OA is an area that is disposed in the display area DA and where a through hole TH is disposed. In the display panel DP, the through hole TH is disposed in the display area DA so that a bezel area as a non-display area NDA decreases while the display area DA is maximized. Products with a maximum display area DA may maximize the user's immersive filling toward a screen and may be preferred from an aesthetic perspective.

The through hole TH may be formed to correspond to an optical electronic device such as a camera or an optical sensor.

As shown in FIG. 1, two through holes TH may be provided, but not limited. For example, one or two holes may be disposed in the display area DA, and a camera may be disposed in the first hole, and a distance sensor or a face recognition sensor and a wide-angle camera may be disposed in the second hole.

The non-display area NDA is an area where an image is not displayed.

The non-display area NDA may bend and not be seen from forward or may be covered by a case (not illustrated), and may be referred to as a bezel area.

In FIG. 1, the non-display area NDA surrounds the display area DA having a rectangle shape, but the shapes and positions of the display area DA and the non-display area NDA are not limited to the examples illustrated in FIG. 1. That is, the display area DA and the non-display area NDA may have a shape appropriate for the design of an electronic device equipped with a display device 100. For example, the display area DA may be shaped into a pentagon, a hexagon, a circle, an oval and the like.

In the non-display area NDA, a variety of lines and circuits for driving a light emitting element of the display area DA, and the like may be disposed. For example, in the non-display area NDA, a link line for delivering a signal to a plurality of sub pixels and circuits of the display area DA, a gate-in-panel (GIP) line, or a driving IC such as a gate driver GD and a data driver DD and the like may be disposed, but not limited thereto.

The display device 100 may further comprise a variety of additional elements for generating a variety of signals or driving a pixel in the display area DA. An additional element for driving a pixel may comprise an inverter circuit, a multiplexer, an electrostatic discharge (ESD) circuit and the like. The display device 100 may comprise an additional element in relation to a function except for driving of a pixel. For example, the display device 100 may further comprise additional elements providing a touch sensing function, a user recognition function (e.g., a fingerprint recognition), a multi-level pressure sensing function, a tactile feedback function and the like. The additional elements described above may be placed at an outside circuit connecting to the non-display area NDA and/or a connection interface.

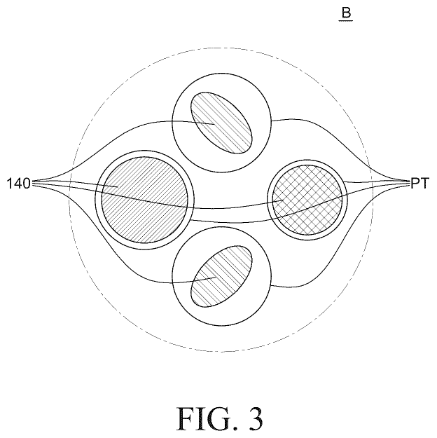

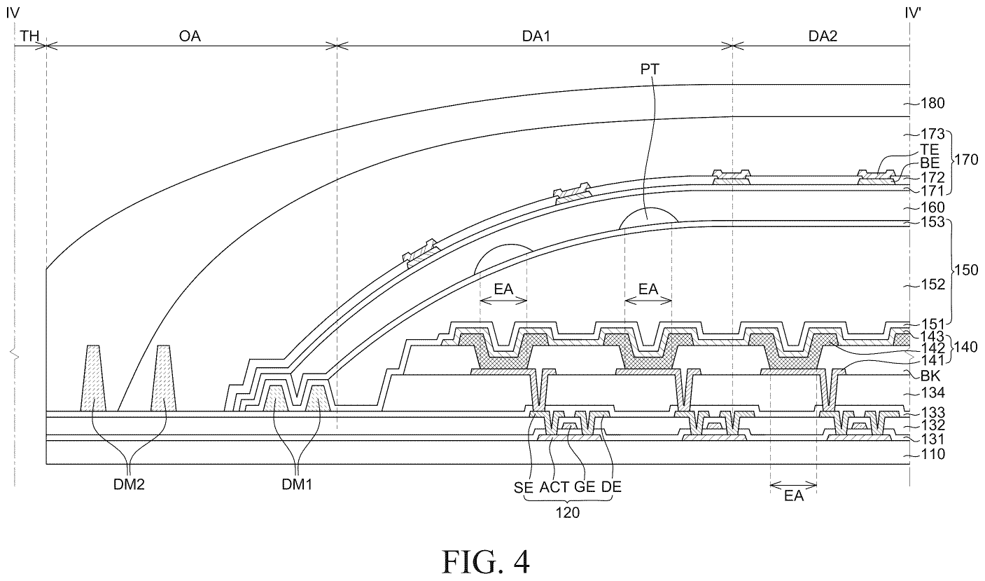

FIG. 2 is a plan view showing area A of FIG. 1 in an enlarged manner according to one embodiment. FIG. 3 is a plan view showing area B of FIG. 2 in an enlarged manner according to one embodiment. FIG. 4 is a cross-sectional view along IV-IV′ of FIG. 2 according to one embodiment.

Referring to FIGS. 2 and 4, the optical area OA has a through hole TH for disposing an optical electronic device, at the center thereof, and in the through hole TH, a camera module or a sensor may be disposed. The optical area OA may comprise a through hole TH having a circle shape or an oval shape and at least one dam DM1, DM2 adjacent to the through hole TH. The through hole TH may be removed by a laser in a panel completion step. Accordingly, the through hole TH may be formed in such a way that the through hole TH penetrates a third planarization layer 180 physically from a substrate 110.

At least one dam DM1, DM2 may be disposed to surround the through hole TH in the optical area OA. At least one dam DM1, DM2 may be disposed between the through hole TH and the display area DA. At least one dam DM1, DM2 may be disposed to surround an organic encapsulation layer 152, and by doing so, the organic encapsulation layer 152 may be prevented from flowing over the through hole TH. Additionally, at least one dam DM1, DM2 may be disposed closer to the through hole TH than a plurality of patterns PT. At least one dam DM1, DM2 may comprise a first dam DM1 and a second dam DM2. Further, in FIG. 2, two first dams DM1 and two second dams DM2 are disposed, but not limited, and as shown in

FIG. 4, more or less first dams DM1 and more or less second dams DM2 may be disposed.

The first dam DM1 may be shaped into a closed curve surrounding the outer edge of the through hole TH. The first dam DM1 may be disposed closer to the display area DA than the second dam DM2. That is, the first dam DM1 may prevent or at least reduce the overflow of the organic encapsulation layer 152 primarily. Accordingly, the organic encapsulation layer 152 may be formed by the first dam DM1 from the display area DA to the inside of the first dam DM1. Further, in the drawing, the first dam DM1 is comprised of one layer, but not limited thereto. That is, the first dam DM1 may be comprised of multiple layers.

The second dam DM2 may be shaped into a closed curve surrounding the outer edge of the through hole TH. The second dam DM2 may be disposed closer to the through hole TH than the first dam DM1. That is, the second dam DM2 may prevent the overflow of a partial organic encapsulation layer 152 flowing over the first dam DM1. Further, in the drawing, the second dam DM2 is comprised of one layer, but not limited thereto. That is, the second dam DM2 may be comprised of multiple layers.

Around the optical area OA, the display area DA surrounding the optical area OA is disposed. The display area DA comprises a first display area DA1 adjacent to the optical area OA and a second display area DA2 surrounding the first display area DA1. The display area DA may comprise a plurality of pixels P.

Referring to FIG. 3, each of the plurality of pixels P may comprise at least one light emitting element 140. In the first display area DA1, a plurality of patterns PT may be disposed on a plurality of light emitting elements 140, to respectively correspond to each of the plurality of light emitting elements 140. Each of the plurality of patterns PT may be disposed to overlap each of the plurality of light emitting elements 140. On a planar surface, the surface area of each of the plurality of patterns PT may be greater than the surface area of a light emitting area EA of each of the plurality of light emitting elements 140. Accordingly, on a planar surface, the plurality of patterns PT may be disposed to surround the light emitting area EA of the plurality of light emitting elements 140. The shape and size of each of the plurality of light emitting elements 140 may vary on a planar surface.

The plurality of light emitting elements 140 and the plurality of patterns PT are described hereinafter specifically with reference to FIG. 4.

Referring to FIG. 4, the substrate 110 comprises an optical area OA, a first display area DA1, and a second display area DA2. The substrate 110 is a component for supporting various components included in the display device 100 and may be formed of an insulating material. For example, the substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

A transistor 120 driving each pixel P in the display area DA may be disposed on the substrate 110. The transistor 120 may comprise an active layer ACT, a gate electrode GE, a source electrode SE, and a drain electrode DE.

The active layer ACT may be disposed on the substrate 110. The active layer ACT may be formed of polysilicon (p-Si), amorphous silicon (a-Si), or oxide semiconductor, but not limited thereto. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

A gate insulation layer 131 may be disposed on the substrate 110 and the active layer ACT. The gate insulation layer 131 may be made of silicon oxide (SiOx), silicon nitride (SiNx) or multiple layers thereof.

The gate electrode GE may be disposed on the gate insulation layer 131. The gate electrode GE may be disposed on the gate insulation layer 131, in such a way that the gate electrode GE overlaps the active layer AC. The gate electrode GE may be formed of a variety of electrically conductive materials, e.g., magnesium (Mg), aluminum (Al), nickel (Ni), chromium (Cr), molybdenum (Mo), tungsten (W), gold (Au) or an alloy thereof and the like, but not limited thereto.

An interlayer insulation layer 132 may be disposed on the gate insulation layer 131 and the gate electrode GE. The interlayer insulation layer 132 may be made of silicon oxide (SiOx), silicon nitride (SiNx) or multiple layers thereof.

The source electrode SE and the drain electrode DE may be disposed on the interlayer insulation layer. The source electrode SE and the drain electrode DE may electrically connect to the active layer ACT through a contact hole formed at the gate insulation layer 131 and the interlayer insulation layer 132. The source electrode SE and the drain electrode DE may be formed of a variety of electrically conductive materials, e.g., magnesium (Mg), aluminum (Al), nickel (Ni), chromium (Cr), molybdenum (Mo), tungsten (W), gold (Au) or an alloy thereof and the like, but not limited thereto.

On the source electrode SE and the drain electrode DE, a protective layer 133 for insulating the thin film transistor 120 may be disposed. The protective layer 133 may be comprised of a film of an inorganic material, e.g., silicon oxide (SiOx), silicon nitride (SiNx) or multiple layers thereof.

A first planarization layer 134 may be disposed on the protective layer 133. The first planarization layer 134 protects the transistor 120 and planarizes the upper portion thereof. The first planarization layer 134, for example, may be formed of an insulation layer of an organic material such as benzocyclobutene (BCB) or acryl and the like, but not limited thereto.

The light emitting element 140 may be disposed on the first planarization layer 134. The light emitting element 140 may comprise an anode 141, an organic light emitting layer 142, and a cathode 143. The anode 141 may be formed to correspond to the light emitting area EA of each pixel P on the first planarization layer 134. The anode 141 may electrically connect to the drain electrode DE of the transistor 120 through a contact hole of the first planarization layer 134. The anode 141 may be formed of a metallic material.

In the case where the display device 100 is based on a top emission method in which light emitted from the light emitting element 140 is emitted toward the upper portion of the substrate 110 on which the light emitting element 140 is disposed, the anode 141 may further comprise an electrically conductive transparent layer and a reflective layer on the electrically conductive transparent layer. The electrically conductive transparent layer, for example, may be made of an electrically conductive transparent oxide such as ITO, IZO and the like, and the reflective layer, for example, may be made of silver (Ag), aluminum (Al), gold (Au), molybdenum (Mo), tungsten (W), chromium (Cr) or an alloy thereof and the like, but not limited thereto.

A bank layer BK may be formed in the remaining area except for the light emitting area EA. Accordingly, the bank layer BK may expose the anode 141 corresponding to the light emitting area EA. The bank layer BK may be made of an inorganic insulation material such as silicon nitride (SiNx), and silicon oxide (SiOx) or an organic insulation material such as benzocyclobutene-based resin or acryl-based resin or imide-based resin, but not limited thereto.

Though not illustrated, a spacer may be further formed on the bank layer BK. The spacer may be formed of a material the same as that of the bank layer BK. The spacer may prevent damage to the light emitting element 140, caused by a fine metal mask FMM that is used in the case where the organic light emitting layer 142 is patterned.

The organic light emitting layer 142 is disposed on the anode 141 exposed by the bank layer BK. The organic light emitting layer 142 may comprise a hole injection layer, a hole transport layer, a light emitting layer, an electron transport layer, an electron injection layer and the like. The organic light emitting layer 142 may have a single light emitting layer structure that emits one light, or a structure that is comprised of multiple light emitting layers and emits white light.

The cathode 143 may be disposed on the organic light emitting layer 142. The cathode 143 may be made of an electrically conductive material of low work function to provide an electron of the organic light emitting layer 142. The cathode 143 may be shaped into one layer across the plurality of pixels P. That is, the cathode 143 of each of the plurality of pixels P may connect to each other and be formed integrally, but not limited thereto.

An encapsulation part 150 comprising a first inorganic encapsulation layer 151, an organic encapsulation layer 152 and a second inorganic encapsulation layer 153 may be disposed on the cathode 143. The encapsulation part 150 may protect the light emitting element 140 from moisture and oxygen. In the case where the light emitting element 140 is exposed to moisture or oxygen, pixel shrinkage where the light emitting element 140 shrinks may be caused, or a dak spot may be caused in the light emitting area EA.

The encapsulation part 150 may comprise a first inorganic encapsulation layer 151, an organic encapsulation layer 152 on the first inorganic encapsulation layer 151, and a second inorganic encapsulation layer 153 on the organic encapsulation layer 152.

The first inorganic encapsulation layer 151 may be disposed on the cathode 143, and cover the lateral surface of the first planarization layer 134 together with the upper surface of the cathode 143 and at least a portion of the upper surface of the bank layer BK and the lateral surface of the bank layer BK. Accordingly, the first inorganic encapsulation layer 151 may prevent the infiltration of moisture and oxygen into the light emitting element 140.

The organic encapsulation layer 152 may be disposed on the first inorganic encapsulation layer 151, and disposed to cover the upper surface and the lateral surface of the first inorganic encapsulation layer 151. The organic encapsulation layer 152 planarizes the upper surface of the first inorganic encapsulation layer 151. Additionally, in the optical area OA that is an area where an image is not displayed, elements such as a transistor 120 or a light emitting element 140 and the like for displaying an image may not be disposed. Accordingly, the height of an uppermost layer among the elements of the optical area OA may be less than the height of an uppermost layer among the elements of the display area DA. Thus, a step may be formed between the optical area OA and the display area DA. The organic encapsulation layer 152 is disposed from the display area DA to the optical area OA in a connected manner, and planarizes the upper surface of the first inorganic encapsulation layer 151 having a step. However, because of the physical properties of the organic encapsulation layer 152, the organic encapsulation layer 152 tends to flow. Accordingy, the height of the upper surface of the organic encapsulation layer 152 may become low toward the optical area OA from the display area DA because of the step between the display area DA and the optical area OA. Thus, in the first display area DA1 adjacent to the optical area OA, the upper surface of the organic encapsulation layer 152 may incline toward the optical area OA. Further, in the second display area DA2 that has no step since the first display area DA2 is spaced from the optical area OA, the upper surface of the organic encapsulation layer 152 may be planar.

The second inorganic encapsulation layer 153 may be disposed on the organic encapsulation layer 152. The second inorganic encapsulation layer 153 may be disposed along the upper surface of the organic encapsulation layer 152. Accordingly, the second inorganic encapsulation layer 153 may have a shape corresponding to the shape of the upper surface of the organic encapsulation layer 152. Specifically, the second inorganic encapsulation layer 153 may be inclined in the first display area DA1, and be planar in the second display area DA2. The second inorganic encapsulation layer 153 may completely cover the first inorganic encapsulation layer 151 and the organic encapsulation layer 152. For example, the second inorganic encapsulation layer 153 may cover the upper surface of the organic encapsulation layer 152, at least a portion of the upper surface of the first inorganic encapsulation layer 151, and the lateral surface of the first inorganic encapsulation layer 151. Accordingly, the first inorganic encapsulation layer 151 and the second inorganic encapsulation layer 153 may contact each other past the end of the organic encapsulation layer 152. By doing so, the second inorganic encapsulation layer 153 may prevent moisture and oxygen from infiltrating into the organic encapsulation layer 152 and the first inorganic encapsulation layer 151.

The first inorganic encapsulation layer 151 and the second inorganic encapsulation layer 153 may be comprised of an inorganic insulation layer. For example, the first inorganic encapsulation layer 151 and the second inorganic encapsulation layer 153 may be formed of an inorganic insulation material such as silicon nitride (SiNx), silicon oxide (SiOx), silicon oxynitride (SiON) or aluminum oxide (Al₂O₃), but not limited thereto. The organic encapsulation layer 152 may be comprised of an organic insulation layer. For example, the organic encapsulation layer 152 may comprise acryl resin or epoxy resin and the like, but not be limited thereto.

In the optical area OA, the organic encapsulation layer 152 constituting the encapsulation part 150 or at least one dam DM1, DM2 blocking the flow of a touch planarization layer 173 and/or the organic encapsulation layer 152 and the like may be disposed. Specifically, at least one dam DM1, DM2 may be respectively disposed in the form of a closed curve surrounding the display area DA in the optical area OA. At least one dam DM1, DM2 may comprise one or more first dams DM1 and one or more second dams DM2. At this time, the first dam DM1 may be disposed closer to the display area DA than the second dam DM2. For example, the first dam DM1 may have a size larger than that of the second dam DM2.

The first inorganic encapsulation layer 151 and the second inorganic encapsulation layer 153 may be disposed on one or more first dams DM1, and the flow of the organic encapsulation layer 152 may be blocked by one or more first dams DM1. For example, the flow of the organic encapsulation layer 152 may be blocked by a dam closest to the display area DA out of one or more first dams DM1, or blocked between one or more first dams DM1. The first inorganic encapsulation layer 151 and the second inorganic encapsulation layer 153 may be disposed to cover one or more first dams DM1. Accordingly, the ends of the first inorganic encapsulation layer 151 and the second inorganic encapsulation layer 153 may be closer to the optical area OA than a first dam DM1 closest to the optical area OA out of one or more first dams DM1.

The second dam DM2 may prevent or at least reduce the flow of the organic encapsulation layer 152 that may flow over the first dam DM1, again. Additionally, the second dam DM2 may block the overflow of the touch planarization layer 173 to the through hole TH. At least one dam DM1, DM2 may have a predetermined height or greater to prevent the flow of the organic encapsulation layer 152 or the touch planarization layer 173 and the like. To this end, at least one dam DM1, DM2 may be comprised of one or more layers made of at least an organic material. For example, at least one dam DM1, DM2 may comprise a lower layer made of the same material as the first planarization layer 134, and an upper layer made of the same material as the bank layer BK, but not be limited thereto. In the drawing, two first dams DM1 and two second dams DM2 are illustrated, but not limited thereto, and the first dam DM1 and the second dam DM2 may be respectively provided as one or three or more ones.

A plurality of patterns PT are disposed on the encapsulation part 150 in the first display area DA1. The plurality of patterns PT are disposed on an inclination surface on the encapsulation part 150. The plurality of patterns PT are disposed to overlap the light emitting area EA of each of the plurality of light emitting elements 140 disposed in the first display area DA1. The plurality of patterns PT may include a transparent material. Each of the plurality of patterns PT may be shaped into a convex lens, and formed in an exposure process, but the present disclosure is not limited thereto, and other various shapes may also be possible. The plurality of patterns PT may be made of a low-temperature photoacryl PAC material that may be formed in a process at low temperature of 100° C. or less, but not limited thereto. For example, each of the plurality of patterns PT may comprise polytriazine or a material where one or more of TiO₂, ZrO₂ and nano filler are included in polytriazine, but not be limited thereto.

In the drawing, the plurality of patterns PT are not disposed on the encapsulation part 150 in the second display area DA2, but not limited thereto. For example, the plurality of patterns PT may be disposed in the second display area DA2 on the encapsulation part 150. At this time, each of the plurality of patterns PT may overlap the light emitting area EA of each of the plurality of light emitting elements 140 disposed in the second display area DA2.

A second planarization layer 160 may be disposed on the plurality of patterns PT. The second planarization layer 160 may be disposed to cover the plurality of patterns PT. Accordingly, the second planarization layers 160 may planarize the upper portion of the plurality of patterns PT. The second planarization layer 160 may incline in the first display area DA1 and may be planar in the second display area DA2.

The second planarization layer 160 may comprise acryl resin or epoxy resin and the like, but not be limited thereto.

A touch part 170 may be disposed on the second planarization layer 160. For example, the touch part 170 may comprise a touch buffer layer 171 disposed on the second planarization layer 160, a bridge electrode BE disposed on the touch buffer layer 171, a touch interlayer insulation layer 172 disposed on the touch buffer layer 171 and the bridge electrode BE, and a plurality of touch electrodes TE disposed on the touch interlayer insulation layer 172.

The touch buffer layer 171 may be formed to cover at least a portion of one or more first dams DM1 disposed in the optical area OA. The touch buffer layer 171 may be disposed on the second planarization layer 160 in the display area DA and the optical area OA. Additionally, the touch buffer layer 171 may contact the second inorganic encapsulation layer 153 past the end of the second planarization layer 160. For example, the touch buffer layer 171 may cover the end of the second inorganic encapsulation layer 153. The touch buffer layer 171 may incline in the first display area DA1, and may be planar in the second display area DA2.

The touch buffer layer 171 may block a liquid chemical such as a developing solution or an etching solution used in manufacturing of the plurality of touch electrodes TE formed on the touch buffer layer 171 or external moisture or foreign substances from infiltrating into the light emitting element.

The bridge electrode BE may be disposed on the touch buffer layer 171. The bridge electrode BE may be disposed in the display area DA, and electrically connect the plurality of touch electrodes TE on the touch interlayer insulation layer 172.

The bridge electrode BE may be disposed in a layer different from the layer of the plurality of touch electrodes TE, and connect to an adjacent touch electrode TE through a contact hole.

At this time, the contact hole may be formed in such a way that the contact hole penetrates the touch interlayer insulation layer 172.

The touch interlayer insulation layer 172 may be disposed between the bridge electrodes BE, on the touch buffer layer 171, to cover the bridge electrodes BE, and insulate the bridge electrodes BE from each other.

The touch interlayer insulation layer 172 may be formed to extend up to the optical area OA as well as the display area DA. In the first display area DA1, the touch interlayer insulation layer 172 may comprise an inclination surface, and in the second display area DA2, the interlayer insulation layer 172 may comprise a planar surface. The touch interlayer insulation layer 172 may be formed to cover the plurality of first dams DM1, and accordingly, reduce a step caused by the plurality of first dams DM1. Additionally, the touch interlayer insulation layer 172 may cover the end of the touch buffer layer 171.

The plurality of touch electrodes TE may be disposed on the touch interlayer insulation layer 172. The plurality of touch electrodes TE, for example, may comprise a first touch electrode that is a touch driving electrode, and a second touch electrode that is a touch sensing electrode. The first touch electrode may be connected in a first direction and form a plurality of electrode columns, and the second electrode may be connected by the bridge electrode BE in a row direction and form a plurality of electrode rows. In this case, the plurality of touch electrodes TE are formed in a mutual-capacitance scheme, but the present disclosure is not limited thereto. For example, the plurality of touch electrodes TE may formed in a self-capacitance scheme in which only touch sensing electrodes are included therein, and the bridge electrode BE may be omitted accordingly.

The plurality of touch electrodes TE may be disposed not to overlap (e.g., non-overlapping) the plurality of patterns PT. Accordingly, the plurality of touch electrodes TE may not overlap the plurality of light emitting elements 140. The plurality of touch electrodes TE may be disposed in an area corresponding to the area of the bank layer BK. Accordingly, the plurality of touch electrodes TE may not overlap the light emitting area EA to minimize a decrease in the light output efficiency.

The plurality of touch electrodes TE may be disposed in an area corresponding to the display area DA, and may be disposed in both of the first display area DA1 and the second display area DA2. In the first display area DA1, the plurality of touch electrodes TE may be disposed on the inclined upper surface of the touch interlayer insulation layer 172, and in the second display area DA2, may be disposed on the planar upper surface of the touch interlayer insulation layer 172. The exterior shape of the plurality of touch electrodes TE is not limited. For example, the exterior shapes of the first touch electrode and the second touch electrode may have a mesh pattern comprising a plurality of rhombus shapes.

The plurality of touch electrodes TE may be made of metal comprising any one of titanium (Ti), aluminum (Al), molybdenum (Mo), molybdenum titanium (MoTi), copper (Cu) and tantalum (Ta), or made of an electrically conductive transparent material such as indium tin oxide (ITO), indium zinc oxide (IZO) and the like, but not limited thereto. Light emitted from the display device 100 may pass through at least a portion of the plurality of touch electrodes TE made of an electrically conductive transparent material and be emitted outward, but may not be limited thereto. Light emitted from the display device 100 may be emitted outward through a plurality of openings included in the plurality of touch electrodes TE.

The touch planarization layer 173 may be disposed on the plurality of touch electrodes TE to cover the upper surface and the lateral surface of the plurality of touch electrodes TE.

The touch planarization layer 173 is disposed to cover the plurality of touch electrodes TE and planarize the upper portion of the plurality of touch electrodes TE. Additionally, the touch planarization layer 173 may be made of an organic material having flowability. Accordingly, the touch planarization layer 173 may incline further toward the optical area OA from the display area DA. That is, in the first display area DA1, the touch planarization layer 173 may comprise an inclination surface, and in the second display area DA2, the touch planarization layer 173 may comprise a planar surface. The touch planarization layer 173 may cover the touch interlayer insulation layer 172 thereunder and cover the plurality of first dams DM1. The flow of the touch planarization layer 173 to the optical area OA may be blocked by at least one of the plurality of second dams DM2.

The touch planarization layer 173 may comprise an organic material having flowability. The touch planarization layer 173, for example, may comprise acryl resin or epoxy resin and the like, but not be limited thereto.

The thickness of the touch part 170 comprising the touch buffer layer 171, the touch interlayer insulation layer 172 and the touch planarization layer 173 may be greater than the thickness of the plurality of patterns PT. In one embodiment, the thickness of the plurality of patterns PT denotes the thickness of the thickest portion of any one of the plurality of patterns PT. Additionally, in the case where the thickness of the touch part 170 differs respectively in the optical area OA, the first display area DA1 and the second display area DA2, the thickness of the touch part 170 denotes the thickness of the thinnest portion of the touch part 170.

The third planarization layer 180 may be disposed on the touch part 170. Since the third planarization layer 180 is not restricted by flowability, the third planarization layer 180 may be applied entirely to the optical area OA and the display area DA. The third planarization layer 180 may cover all the elements disposed thereunder. The third planarization layer 180 may be disposed to cover all the plurality of second dams DM2. Accordingly, the third planarization layer 180 may reduce the inclination of the first display area DA1. Accordingly, the third planarization layer 180 may reduce a step in the uppermost layer of the second display area DA2 and the optical area OA.

The third planarization layer 180 may comprise an organic material having flowability. The third planarization layer 180, for example, may comprise acryl resin or epoxy resin and the like, but not be limited thereto.

The refractive index of the third planarization layer 180 may be less than that of the touch planarization layer 173 disposed thereunder. Additionally, the refractive index of the touch planarization layer 173 may be less than that of the plurality of patterns PT. That is, among element layers disposed on the encapsulation part 150, the refractive indices of elements comprising an organic material may decrease further toward an upper element.

In the case of a display device comprising a through hole, the high potential power line and the gate line and the like are disposed around the through hole in such a way that the high potential power line and the gate line and the like detour or bypass the through hole. Accordingly, an optical area is formed where a variety of lines detouring the surroundings of the through hole, and a structure such as one or more dams for preventing the infiltration of moisture or oxygen into the light emitting element of the display area from the through hole and the like are disposed. In the optical area, the light emitting element is not disposed, and accordingly, an image is not displayed in the optical area. In the optical area, an element such as a light emitting element and a transistor for driving the light emitting element and the like are not disposed, so that the height of the uppermost layer of the optical area is lower than the height of the uppermost layer of the display area. Accordingly, a step is made between the uppermost layer of the display area and the uppermost layer of the optical area, and the step causes deterioration in visibility such as a reduction in the luminance of an area having the step and a portion around the area, and the like. To solve the problem, research has been conducted into disposition of a planarization layer comprising an organic material on the uppermost layers of the display area and the optical area. However, despite disposition of a planarization layer having flowability, a step is still made between the optical area and the display area, and deterioration in visibility remains unsolved.

To solve the problem, in the display device 100 of one embodiment, the plurality of light emitting elements 140 is disposed in the first display area DA1 having a step near the optical area OA, so that the luminance of the first display area DA1 near the optical area OA may improve.

Further, in the first display area DA1, the plurality of patterns PT respectively corresponding to each of the plurality of light emitting elements 140 is disposed on the plurality of light emitting elements 140, so that the collection efficiency and output efficiency of light emitted from the light emitting elements 140 may improve. By doing so, the luminance efficiency of the first display area DA1 adjacent to the optical area OA may improve.

Further, in the case of a display device 100 of one embodiment, the plurality of patterns PT may be disposed between the encapsulation part 150 and the touch part 170, in the first display area DA1. Since the plurality of patterns PT is included in the first display area DA1 having an inclination surface as described above, the height of the upper surface of the elements disposed on the plurality of patterns PT may become high. By doing so, the step between the first display area DA1 and the second display area DA2 is reduced, so that the inclination of the first display area DA1 may become gentle. Thus, deterioration in luminance, caused by the step, may be minimized in the first display area DA1 near the optical area OA.

Further, in the display device 100 of one embodiment, any of the plurality of patterns PT, the touch planarization layer 173 and the third planarization layer 180, which is disposed further upward, may have a lower refractive index that the others which are lower disposed. By doing so, loss of light emitted from the plurality of light emitting elements 140, caused by total reflection, may be suppressed. Thus, luminance in the first display area DA1 may improve further.

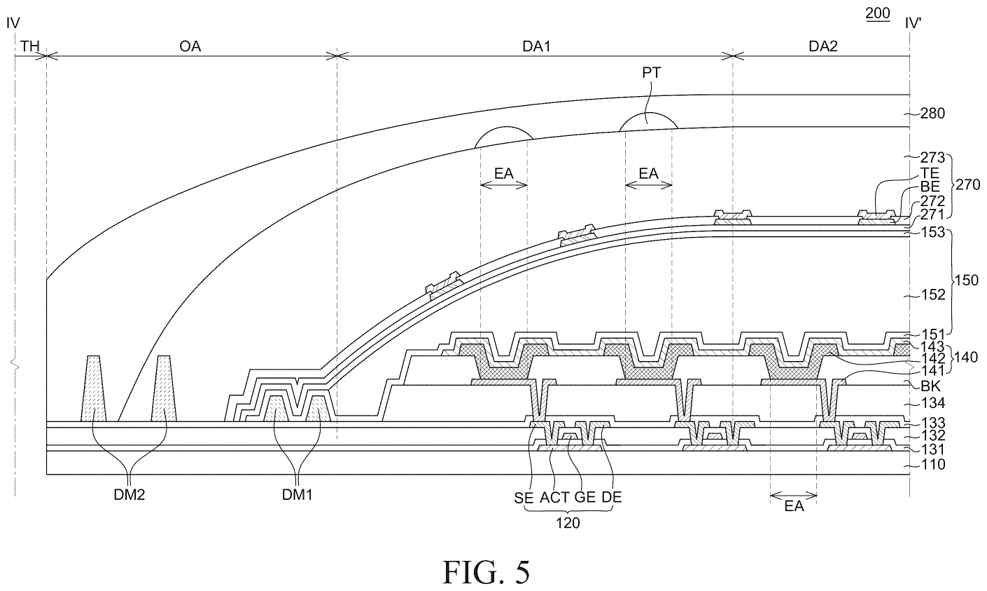

FIG. 5 is a cross-sectional view along IV-IV' of FIG. 2 in another embodiment. A display device 200 of FIG. 5 is substantially the same as the display device 100 of FIGS. 1-4 except for the disposition of a touch part 270, a plurality of patterns PT and a third planarization layer 280, and accordingly, description of common elements of the display devices may be omitted or briefly given hereinafter.

Referring to FIG. 5, in the display device 200 of another embodiment, a touch part 270 comprising a touch buffer layer 271, a touch interlayer insulation layer 272, a touch electrode TE, a bridge electrode BE, and a touch planarization layer 273 may be disposed on the encapsulation part 150.

For example, the touch buffer layer 271 may be disposed on the encapsulation part 150. A plurality of bridge electrodes BE may be disposed on the touch buffer layer 271, and the touch electrode TE connecting to the bridge electrode BE may be disposed on the bridge electrodes BE. The touch electrode TE may be disposed between the plurality of light emitting areas EA, and disposed not to overlap the plurality of light emitting areas EA. The touch interlayer insulation layer 272 may be disposed between the plurality of bridge electrodes BE and the plurality of touch electrodes TE. The touch planarization layer 273 may be disposed on the plurality of touch electrodes TE. The touch planarization layer 273 may be disposed to cover the plurality of touch electrodes, and cover all the lower elements of the first display area DA1 and the second display area DA2. Additionally, the touch planarization layer 273 may extend up to the optical area OA. The touch planarization layer 273 may be disposed to cover the plurality of first dams DM1, and cover at least one of the plurality of second dams DM2. For example, the end of the touch planarization layer 273 may be disposed between the plurality of second dams DM2. Accordingly, the end of the touch planarization layer 273 may not be disposed on a second dam DM2 disposed closest to the through hole TH among the plurality of second dams DM2.

The plurality of patterns PT may be disposed on the touch part 270. The plurality of patterns PT may be disposed to overlap the light emitting area EA, on the touch part 270. At this time, each of the plurality of patterns PT may be disposed to cover each of the plurality of light emitting areas EA. For example, the surface area of the lower surface of the plurality of patterns PT may be greater than the surface area of the light emitting area EA. The plurality of patterns PT may be disposed in the first display area DA1. Though not illustrated in the drawing, the plurality of patterns PT may also be disposed in the second display area DA2. The thickness of the plurality of patterns PT may be less than the thickness of the touch part 270.

The third planarization layer 280 may be disposed on the plurality of patterns PT. The third planarization layer 280 may be disposed to cover all the plurality of patterns PT. The third planarization layer 280 may cover both of the first display area DA1 and the second display area DA2. Additionally, the third planarization layer 280 may be disposed to cover the optical area OA. For example, the third planarization layer 280 may be disposed to cover the plurality of first dams DM1 and the plurality of second dams DM2. The third planarization layer 280 may also be disposed on a second dam DM2 closest to the through hole TH among the plurality of second dams DM2.

The refractive indices of the touch planarization layer 273, the plurality of patterns PT and the third planarization layer 280 may differ from one another. The third planarization layer 280 may have the least refractive index, and the touch planarization layer 273 may have the greater refractive index. For example, the refractive index of the touch planarization layer 273 may be greater than the refractive index of the plurality of patterns PT, and the refractive index of the plurality of patterns PT may be greater than the refractive index of the third planarization layer 280.

In the display device 200 of another embodiment, the plurality of light emitting elements 140 is disposed in the first display area DA having a step near the optical area OA, so that the luminance of the first display area DA1 adjacent to the optical area OA improves.

Additionally, the plurality of patterns PT respectively corresponding to each of the plurality of light emitting elements 140 are disposed on the touch part 270 in the first display area DA1, so that the collection efficiency and output efficiency of light emitted from the light emitting elements 140 improves.

Further, in the display device 200 of another embodiment, the plurality of patterns PT may be disposed on the touch part 270, in the first display area DA1. Accordingly, the height of the upper surface of the third planarization layer 280 disposed on the plurality of patterns PT in the first display area DA1 may become high. By doing so, the step between the first display area DA1 and the second display area DA2 may decrease, and deterioration in luminance, caused by the step, may be minimized.

Furthermore, in the display device 200 of another embodiment, a refractive index may decrease further toward the touch planarization layer 273, the plurality of patterns PT and the third planarization layer 280. Thus, the extinction of light emitted from the plurality of light emitting elements 140, caused by total reflection, may be prevented.

The exemplary embodiments of the present disclosure can also be described as follows:

According to an embodiment of the present disclosure, there is provided a display device. The display device comprises a substrate comprising an optical area comprising a through hole, a first display area and a second display area, the first display area located between the optical area and the second display area, a plurality of light emitting elements disposed on the substrate, and a plurality of patterns disposed on the plurality of light emitting elements in the first display area, in such a way that the plurality of patterns respectively corresponds to each of the plurality of light emitting elements.

The first display area may surround the optical area and the second display area may surround the first display area.

The display device may further comprise an encapsulation part disposed on the plurality of light emitting elements. An upper surface of the encapsulation part may incline in the first display area, and the upper surface of the encapsulation part may be planar in the second display area.

The upper surface of the encapsulation part may incline toward the optical area.

The display device may comprise a touch part disposed on the encapsulation part, and configured to comprise a plurality of touch electrodes, and the plurality of touch electrodes may be disposed not to overlap the plurality of patterns.

The plurality of patterns may be disposed between the touch part and the encapsulation part.

The touch part may further comprise at least one touch planarization layer, the display device may further comprise a planarization layer on the touch part. Among the plurality of patterns, the touch planarization layer and the planarization layer, the planarization layer may have a least refractive index, and the plurality of patterns may have a greatest refractive index.

The plurality of patterns may be disposed on the touch part.

The display device may further comprise a planarization layer on the plurality of patterns, and the touch part may further comprise at least one touch planarization layer. Among the touch planarization layer, the plurality of patterns, and the planarization layer, the planarization layer may have a least refractive index, and the touch planarization layer may have a greatest refractive index.

The encapsulation part may comprise a first inorganic encapsulation layer, an organic encapsulation layer on the first inorganic encapsulation layer, and a second inorganic encapsulation layer on the organic encapsulation layer. The display device may further comprise one or more dams disposed to surround the organic encapsulation layer, and

the one or more dams are disposed closer to the through hole than the plurality of pattens.

The one or more dams may be disposed in the optical area and include a first dam and a second dam disposed closer to the through hole than the first dam.

Each of the first dam and the second dam may be disposed in form of a closed curve.

A thickness of the touch part may be greater than a thickness of the plurality of patterns.

A surface area of a planar surface of each of the plurality of patterns may be greater than a surface area of a planar surface of each of the plurality of light emitting elements. Each of the plurality of patterns may have a lens shape.

The plurality of patterns may be disposed on an inclination surface.

Each of the plurality of patterns may be disposed to overlap each of the plurality of light emitting elements.

On a planar surface, each of the plurality of patterns may be disposed to surround a light emitting area of each of the plurality of light emitting elements.

According to another aspect of the present disclosure, there is provided a display device comprising: a substrate comprising an optical area comprising a through hole, a first display area and a second display area, the first display area located between the optical area and the second display area; a plurality of light emitting elements disposed in the first display area and the second display area on the substrate; and a plurality of patterns disposed on an inclination surface in the first display area.

The plurality of patterns may be disposed over the plurality of light emitting elements in the first display area, such that the plurality of patterns respectively overlap with the plurality of light emitting elements.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all embodiments and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate comprising an optical area having a through hole, a first display area and a second display area, the first display area located between the optical area and the second display area;
a plurality of light emitting elements on the substrate; and
a plurality of patterns on the plurality of light emitting elements in the first display area such that the plurality of patterns respectively correspond to the plurality of light emitting elements.

2. The display device of claim 1, wherein the first display area surrounds the optical area and the second display area surrounds the first display area.

3. The display device of claim 1, wherein the display device further comprises:
an encapsulation part on the plurality of light emitting elements,
wherein an upper surface of the encapsulation part inclines in the first display area, and the upper surface of the encapsulation part is planar in the second display area.

4. The display device of claim 3, wherein the upper surface of the encapsulation part inclines toward the optical area.

5. The display device of claim 3, wherein the display device further comprises:
a touch part on the encapsulation part, the touch part comprising a plurality of touch electrodes,
wherein the plurality of touch electrodes are non-overlapping with the plurality of patterns.

6. The display device of claim 5, wherein the plurality of patterns are between the touch part and the encapsulation part.

7. The display device of claim 6, wherein the touch part further comprises at least one touch planarization layer
the touch part further comprises a planarization layer thereon,
among the plurality of patterns, the at least one touch planarization layer and the planarization layer, the planarization layer has a least refractive index, and the plurality of patterns has a greatest refractive index.

8. The display device of claim 5, wherein the plurality of patterns are on the touch part.

9. The display device of claim 8, further comprising a planarization layer on the plurality of patterns,
the touch part further comprises at least one touch planarization layer, and
among the at least one touch planarization layer, the plurality of patterns, and the planarization layer, the planarization layer has a least refractive index, and the at least one touch planarization layer has a greatest refractive index.

10. The display device of claim 3, wherein the encapsulation part comprises a first inorganic encapsulation layer, an organic encapsulation layer on the first inorganic encapsulation layer, and a second inorganic encapsulation layer on the organic encapsulation layer,
wherein the display device further comprises:
one or more dams surrounding the organic encapsulation layer,
wherein the one or more dams are closer to the through hole than the plurality of patterns.

11. The display device of claim 10, wherein the one or more dams are disposed in the optical area and include a first dam and a second dam disposed closer to the through hole than the first dam.

12. The display device of claim 11, wherein each of the first dam and the second dam is disposed in form of a closed curve.

13. The display device of claim 5, wherein a thickness of the touch part is greater than a thickness of the plurality of patterns.

14. The display device of claim 1, wherein a surface area of a planar surface of each of the plurality of patterns is greater than a surface area of a planar surface of each of the plurality of light emitting elements.

15. The display device of claim 1, wherein each of the plurality of patterns has a convex lens shape.

16. The display device of claim 1, wherein the plurality of patterns is disposed on an inclination surface.

17. The display device of claim 1, wherein each of the plurality of patterns is disposed to overlap each of the plurality of light emitting elements.

18. The display device of claim 17, wherein on a planar surface, each of the plurality of patterns is disposed to surround a light emitting area of each of the plurality of light emitting elements.

19. A display device, comprising:
a substrate comprising an optical area comprising a through hole, a first display area and a second display area, the first display area located between the optical area and the second display area;
a plurality of light emitting elements disposed in the first display area and the second display area on the substrate; and
a plurality of patterns disposed on an inclination surface in the first display area.

20. The display device of claim 19, wherein the plurality of patterns is disposed over the plurality of light emitting elements in the first display area, such that the plurality of patterns respectively overlap with the plurality of light emitting elements.
